(19) United States
(12) Patent Application Publication
(10) Pub. No.: US 2025/0210326 A1
(43) Pub. Date: Jun. 26, 2025

(54) MEMBER FOR SEMICONDUCTOR MANUFACTURING APPARATUS

(71) Applicant: NGK INSULATORS, LTD., Nagoya-City (JP)

(72) Inventors: Seiya INOUE, Handa-City (JP); Hiroshi TAKEBAYASHI, Handa-City (JP)

(73) Assignee: NGK INSULATORS, LTD., Nagoya-City (JP)

(21) Appl. No.: 18/749,776

(22) Filed: Jun. 21, 2024

Related U.S. Application Data
(63) Continuation of application No. PCT/JP2023/045983, filed on Dec. 21, 2023.

(51) Int. Cl. H01J 37/32; H01L 21/683

(52) U.S. Cl. CPC H01J 37/32724; H01J 37/32568; H01L 21/6833; H01J 37/32082; H01J 2237/2001

(57) ABSTRACT

A member for semiconductor manufacturing apparatus includes a first ceramic plate having a wafer placement surface on its upper surface and a built-in electrode; a second ceramic plate disposed on a lower surface side of the first ceramic plate; a cooling plate disposed on a lower surface side of the second ceramic plate; a first bonding layer made of metal, which is used as an RF electrode and configured to bond the lower surface of the first ceramic plate and an upper surface of the second ceramic plate together; and a second bonding layer made of metal or inorganic composition configured to bond the lower surface of the second ceramic plate and an upper surface of the cooling plate together.

### BACKGROUND OF THE INVENTION

### 1. Field of the Invention

The present invention relates to a member for semiconductor manufacturing apparatus.

### 2. Description of the Related Art

Conventionally, a wafer placement table has been known as a member for semiconductor manufacturing apparatus. For example, PTL 1 discloses a wafer placement table including: a ceramic plate having a wafer placement surface on its upper surface and an internally embedded electrode; a cooling plate made of a metal matrix composite material, in which a refrigerant flow path is formed; and a metal bonding layer that bonds the lower surface of the ceramic plate and the upper surface of the cooling plate together. A chamber on which the wafer placement table is installed has a flat plate electrode over the wafer placement surface. In PTL 1, a plasma is generated above the wafer placement surface by applying high-frequency power across the flat plate electrode of the chamber and the metal bonding layer of the wafer placement table.

### CITATION LIST

### Patent Literature

PTL 1: WO2023/037698A1

### SUMMARY OF THE INVENTION

In the wafer placement table of PTL 1, the ceramic plate and the cooling plate are bonded by metal, thus as compared to when a resin is used, the corrosion resistance of the bonding layer is higher, but the wafer is likely to be cooled because the thermal conductivity is higher than that of a resin. To prevent excessive cooling of the wafer, countermeasures may be taken such as increasing the temperature of the refrigerant which flows through the refrigerant flow path, or embedding a heater electrode in the ceramic plate to warm up the ceramic plate by the heater electrode. However, such countermeasures are not preferable because electricity is wastefully consumed. Alternatively, excessive cooling of the wafer may be prevented by increasing the thickness of the ceramic plate. However, when the metal bonding layer is utilized as an RF electrode, a problem arises in that plasma generation efficiency decreases because the distance between the metal bonding layer and the wafer placement surface increases.

The present invention has been devised to solve the above-mentioned problem, and in a member for semiconductor manufacturing apparatus, in which a ceramic plate and a cooling plate are bonded by a bonding layer having a high thermal conductivity, it is a main object to maintain high corrosion resistance of the bonding layer, prevent excessive cooling of the wafer without wastefully consuming electricity and achieve a favorable plasma generation efficiency.
[1] A member for semiconductor manufacturing apparatus of the present invention includes: a first ceramic plate having a wafer placement surface on its upper surface and a built-in electrode; a second ceramic plate disposed on a lower surface side of the first ceramic plate; a cooling plate disposed on a lower surface side of the second ceramic plate; a first bonding layer made of metal, which is used as an RF electrode and configured to bond the lower surface of the first ceramic plate and an upper surface of the second ceramic plate together; and a second bonding layer made of metal or inorganic composition configured to bond the lower surface of the second ceramic plate and an upper surface of the cooling plate together.

The member for semiconductor manufacturing apparatus includes: the first bonding layer made of metal, which is used as an RF electrode and configured to bond the lower surface of the first ceramic plate and the upper surface of the second ceramic plate together; and a second bonding layer made of metal or inorganic composition configured to bond the lower surface of the second ceramic plate and the upper surface of the cooling plate together. The second bonding layer has higher corrosion resistance than a resin. The thickness of the ceramic plate above the second bonding layer includes the thickness of the second ceramic plate in addition to the thickness of the first ceramic plate, thus excessive cooling of the wafer can be prevented without wastefully consuming electricity. In addition, the first ceramic plate is present but the second ceramic plate is not present above the first bonding layer which is used as an RF electrode; thus, a favorable plasma generation efficiency is achieved.

In the present specification, the present invention may be described using upper and lower, right and left, front and back, but the upper and lower, the right and left, the front and back indicate only a relative positional relationship. Thus, when the orientation of the member for semiconductor manufacturing apparatus is changed, the upper and lower may become the right and left, or the right and left may become the upper and lower, and such a case is also included in the technical scope of the present invention. The “RF electrode” is one of a pair of flat plate electrodes to generate a plasma, and may be an electrode to which high-frequency waves are applied (in this case, the other electrode is connected to the ground), or may be an electrode connected to the ground (in this case, high-frequency waves are applied to the other electrode).
[2] In the member for semiconductor manufacturing apparatus (the member for semiconductor manufacturing apparatus according to [1]) of the present invention, it is preferable that the thickness of the first bonding layer be greater than or equal to 0.1 mm and less than or equal to 1 mm. When the thickness is greater than or equal to 0.1 mm, the heat generated when RF propagates the first bonding layer can be reduced, thus plasma can be efficiently generated. In addition, when the thickness is less than or equal to 1 mm, the thermal expansion difference between the first and second ceramic plates and the first bonding layer is unlikely to cause a problem.
[3] In the member for semiconductor manufacturing apparatus (the member for semiconductor manufacturing apparatus according to [1] or [2]) of the present invention, it is preferable that the volume resistivity of the first bonding layer at 20° C. be lower than or equal to 1×10⁻⁴ Ωcm. In this setting, when the first bonding layer is used as an RF electrode, the first bonding layer is unlikely to generate heat due to sufficiently low resistance of the first bonding layer, thus the temperature uniformity of the wafer is unlikely to be impaired.
[4] In the member for semiconductor manufacturing apparatus (the member for semiconductor manufacturing apparatus according to any one of [1] to [3]) of the present invention, it is preferable that the absolute value of the difference between the linear thermal expansion coefficient of the first ceramic plate at 40 to 400° C. and the linear thermal expansion coefficient of the second ceramic plate at 40 to 400° C. be less than or equal to 1.5×10⁻⁶/K. In this setting, occurrence of a problem due to the thermal expansion difference between the first ceramic plate and the second ceramic plate can be reduced.
[5] In the member for semiconductor manufacturing apparatus (the member for semiconductor manufacturing apparatus according to any one of [1] to [4]) of the present invention, it is preferable that the cooling plate be made of metal or a metal ceramic composite material, and the absolute value of the difference between the linear thermal expansion coefficients of the cooling plate at 40 to 400° C. and the second ceramic plate at 40 to 400° C. be less than or equal to 1.5×10⁻⁶/K. In this setting, occurrence of a problem due to the thermal expansion difference between the second ceramic plate and the cooling plate can be reduced.
[6] The member for semiconductor manufacturing apparatus (the member for semiconductor manufacturing apparatus according to any one of [1] to [5]) of the present invention may include an RF electrode hole, through which an RF electrode connection member to be directly connected to the first bonding layer is inserted, is provided from a lower surface of the cooling plate to the first bonding layer penetrating through the cooling plate, the second bonding layer and the second ceramic plate.
[7] In the member for semiconductor manufacturing apparatus (the member for semiconductor manufacturing apparatus according to [6]) of the present invention, the RF electrode hole may have an insulating tube through which the RF electrode connection member is inserted. In this setting, even when the cooling plate or the RF electrode connection member has an electrical conductivity, it is possible to prevent short-circuit due to contact between the RF electrode connection member and the cooling plate or the second bonding layer.

### BRIEF DESCRIPTION OF THE DRAWINGS

FIG. 1 is a vertical cross-sectional view of a wafer placement table 10 installed in a chamber 90.

FIG. 2 is a plan view of the wafer placement table 10.

FIG. 3 is an enlarged view of the portion surrounded by a circular dash-dot-dot line of FIG. 1.

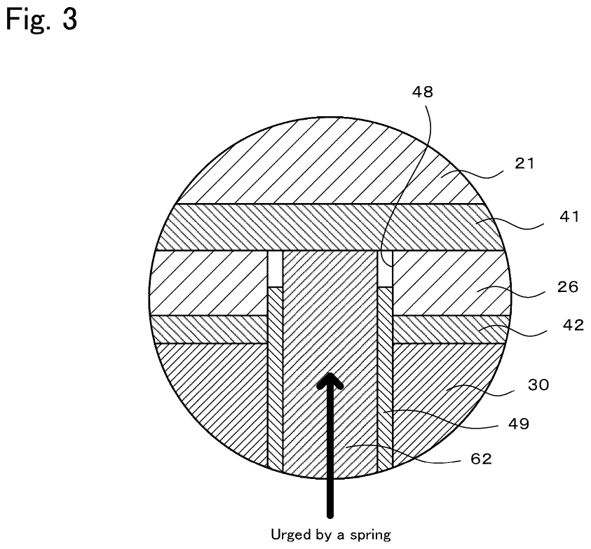

### DETAILED DESCRIPTION OF THE INVENTION

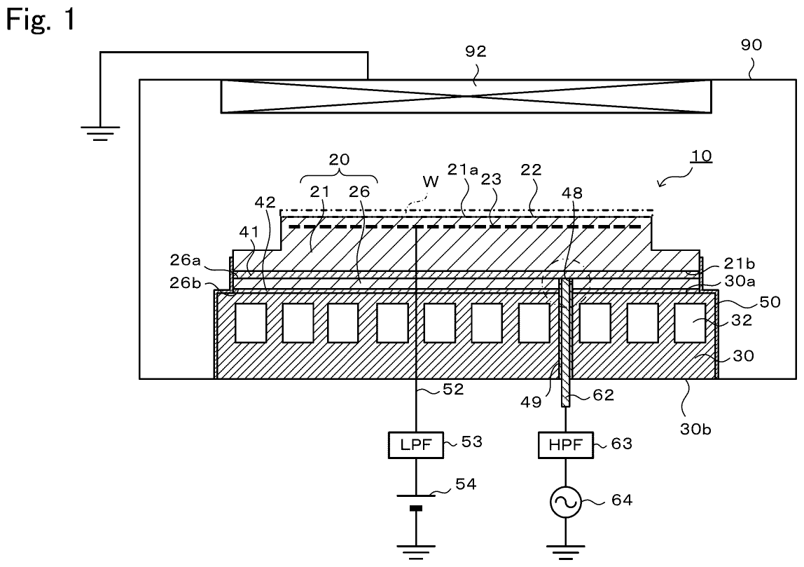

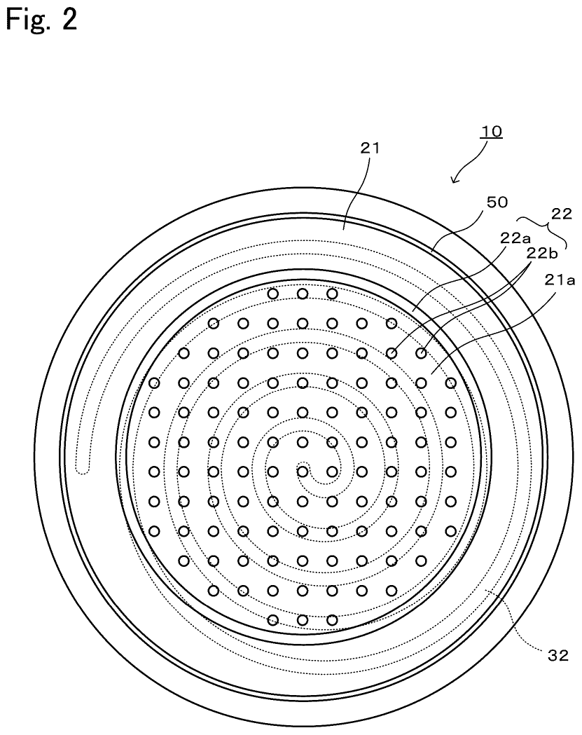

A preferred embodiment of the present invention will be described below with reference to the drawings. FIG. 1 is a vertical cross-sectional view of a wafer placement table 10 installed in a chamber 90. FIG. 2 is a plan view of the wafer placement table 10.

The wafer placement table 10 is an example of a member for semiconductor manufacturing apparatus of the present invention, and is used for performing CVD and etching on a wafer W by utilizing a plasma. As illustrated in FIG. 1, the wafer placement table 10 includes a first ceramic plate 21, a second ceramic plate 26, a cooling plate 30, a first bonding layer 41, and a second bonding layer 42. In this embodiment, a ceramic plate 20 is a bonded body obtained by bonding the first ceramic plate 21 and the second ceramic plate 26 via the first bonding layer 41, and the ceramic plate 20 and the cooling plate 30 are bonded via the second bonding layer 42.

The first ceramic plate 21 is a disc member having a step along the outer circumference. The first ceramic plate 21 is made of a ceramic material represented by alumina, aluminum nitride, and has a circular wafer placement surface 22 on an upper surface 21a. A wafer W is placed on the wafer placement surface 22. As illustrated in FIG. 2, on the wafer placement surface 22, a seal band 22a is formed along the outer edge of the upper surface of the first ceramic plate 21, and a plurality of small circular flat projections 22b are formed on the entire inner surface of the seal band 22a. The seal band 22a and the small circular projections 22b have the same height which is e.g., several μm to several 10 μm. As illustrated in FIG. 1, the first ceramic plate 21 has a built-in electrostatic electrode 23 near the wafer placement surface 22. The electrostatic electrode 23 is a planar mesh electrode which is embedded to cover substantially the entire surface of the wafer placement surface 22 in a plan view. The electrostatic electrode 23 is connected to a direct-current power supply 54 via a power supply member 52. A low pass filter (LPF) 53 is provided between the electrostatic electrode 23 and the direct-current power supply 54. When a direct-current voltage is applied to the electrostatic electrode 23, the wafer W is attracted and fixed to the wafer placement surface 22 (specifically, the upper surface of the seal band 22a and the upper surfaces of the small circular projections 22b) by an electrostatic attraction force, and when the application of the direct-current voltage is stopped, the attraction and fixing of the wafer W to the wafer placement surface 22 is released. The power supply member 52 is electrically insulated from the cooling plate 30, the first and second bonding layers 41, 42.

The second ceramic plate 26 is disposed near a lower surface 21b of the first ceramic plate 21. The second ceramic plate 26 is a disc member having substantially the same diameter as that of the lower surface 21b of the first ceramic plate 21. For the material used for the second ceramic plate 26, the absolute value of the linear thermal expansion coefficient difference between itself and the ceramic material used for the first ceramic plate 21 at 40 to 400° C. is preferably less than or equal to 1.5×10⁻⁶/K, more preferably less than or equal to 1.0×10⁻⁶/K, and further preferably less than or equal to 0.5×10⁻⁶/K. For example, when the first ceramic plate 21 is made of alumina, the second ceramic plate 26 is preferably made of alumina or yttria. The thermal conductivity of the second ceramic plate 26 is preferably less than or equal to that of the first ceramic plate 21. In this setting, the second ceramic plate 26 serves as a thermal resistance layer, and can effectively prevent excessive cooling of the wafer W.

The cooling plate 30 is disposed near the lower surface 26b of the second ceramic plate 26. The cooling plate 30 is a disc member made of a composite material of metal and ceramic, or metal. The diameter of the cooling plate 30 is approximately the same as the diameter of the second ceramic plate 26. As the composite material of metal and ceramic, a metal matrix composite material (metal matrix composite (MMC)) and a ceramic matrix composite material (ceramic matrix composite (CMC)) may be mentioned. As a specific example of such a composite material, a material containing Si, SiC and Ti, a material obtained by impregnating a SiC porous body with Al and/or Si may be mentioned. A material containing Si, SiC and Ti is referred to as SiSiCTi, a material obtained by impregnating a SiC porous body with Al is referred to as AlSiC, and a material obtained by impregnating a SiC porous body with Si is referred to as SiSiC. As the metal, Mo may be mentioned. For the material used for the cooling plate 30, the absolute value of the linear thermal expansion coefficient difference between itself and the ceramic material used for the second ceramic plate 26 at 40 to 400° C. is preferably less than or equal to 1.5×10⁻⁶/K, more preferably less than or equal to 1.0×10⁻⁶/K, and further preferably less than or equal to 0.5×10⁻⁶/K.

The linear thermal expansion coefficients of typical materials at 40 to 400° C. are shown in Table 1.

TABLE 1

| | | Linear thermal expansion |
|---|---|---|
| | | coefficient at 40 to 400° C. |
| Material | | [×10⁻⁶/K] |
| Ceramic | Alumina | 7.2 |
| | Yttria | 7.2 |
| | Aluminum nitride | 4.6 |
| Composite | SiSiCTi | 7.3 |
| material | AlSiC(SiC75%) | 7.8 |
| | AlSiC(SiC85%) | 5.6 |
| Metal | Mo | 5.6 |

The cooling plate 30 has a built-in refrigerant flow path 32 through which a refrigerant can be circulated. The refrigerant flow path 32 is formed from one end (inlet) to the other end (outlet) in a one-stroke pattern over substantially the entire surface of the wafer placement table 10 in a plan view. The refrigerant flow path 32 may be formed e.g., in a swirl shape (FIG. 2), or formed in a zigzag shape in a plan view. The refrigerant is supplied from a refrigerant circulation device which is not illustrated to one end (inlet) of the refrigerant flow path 32, passes through the refrigerant flow path 32, then is discharged from the other end (outlet) of the refrigerant flow path 32, and returns to the refrigerant circulation device. The refrigerant circulation device can adjust the refrigerant at a desired temperature. The refrigerant is preferably liquid, and preferably liquid having electrical insulating properties. As the liquid having electrical insulating properties, e.g., fluorine-based inert liquid may be mentioned.

The first bonding layer 41 is a metal bonding layer that bonds the lower surface 21b of the first ceramic plate 21 and the upper surface 26a of the second ceramic plate 26 together. The first bonding layer 41 is used as an RF electrode. The thickness of the first bonding layer 41 is preferably greater than or equal to 0.1 mm and less than or equal to 1 mm, more preferably greater than or equal to 0.3 mm and less than or equal to 1 mm, and further preferably greater than or equal to 0.3 mm and less than or equal to 0.5 mm. When the RF electrode hole 48 is provided, the thickness of the first bonding layer 41 greater than or equal to 0.1 mm makes it easier to prevent the RF electrode hole 48 from penetrating the first bonding layer 41, and the thickness greater than or equal to 0.3 mm makes it further easier to prevent that. When the thickness of the first bonding layer 41 is less than or equal to 1 mm, the thermal expansion difference between the first and second ceramic plates 21, 26 and the first bonding layer 41 is unlikely to cause a problem (e.g., cracking) of the wafer placement table 10, and when the thickness is less than or equal to 0.5 mm, a problem is further unlikely to occur. The first bonding layer 41 is preferably a layer of Al or Ti, and is formed by, for example, TCB (Thermal compression bonding). The TCB is a publicly known method by which a metal bonding material is inserted between two members to be bonded, and the two members are pressurized and bonded with the two members heated at a temperature lower than or equal to the solidus temperature of the metal bonding material. The volume resistivity of the first bonding layer 41 at 20° C. is preferably less than or equal to 1×10⁻⁴ Ωcm, and more preferably less than or equal to 1×10⁻⁵ Ωcm. For example, Al or Ti may be mentioned as the first bonding layer 41, and the volume resistivities of Al and Ti at 20° C. are 0.28×10⁻⁵ Ωcm, 5.33×10⁻⁵ Ωcm, respectively. Therefore, the first bonding layer 41 is preferably Al.

The second bonding layer 42 is a bonding layer having a higher thermal conductivity than a resin and configured to bond the lower surface 26b of the second ceramic plate 26 and an upper surface 30a of the cooling plate 30 together. The second bonding layer 42 herein is made of metal, for example, Al or Ti. The second bonding layer 42 bonds the lower surface 26b of the second ceramic plate 26 and the upper surface 30a of the cooling plate 30 together without a gap. The thickness of the second bonding layer 42 is preferably about 0.1 mm. The second bonding layer 42 is preferably made of the same material as that of the first bonding layer 41. In this setting, the first bonding layer 41 and the second bonding layer 42 can be collectively bonded, and the number of manufacturing steps can be reduced. The second bonding layer 42 may be a layer formed by TCB (Thermal compression bonding), and may be a layer made of solder or a metal brazing material.

The thermal conductivities of typical materials are shown in Table 2.

TABLE 2

| | | Thermal conductivity |
|---|---|---|
| Material | | [W/m · K] |
| Metal | Al | 237 |
| | Ti | 22 |
| Ceramic | Alumina | 36 |
| | Yttria | 14 |
| | Aluminum nitride | 317 |
| Glass | Quartz glass | 1.38 |
| | Soda glass | 1.03 |
| Resin | Silicone | 0.20 |
| | Acryl | 0.21 |
| | Epoxy | 0.30 |

The RF electrode hole 48 is provided from the lower surface 30b of the cooling plate 30 to the first bonding layer 41 penetrating through the cooling plate 30, the second bonding layer 42 and the second ceramic plate 26. A metal RF rod (RF electrode connection member) 62 to be directly connected to the first bonding layer 41 is inserted into the RF electrode hole 48. The RF rod 62 is inserted into an insulating tube 49 which is fixed to the RF electrode hole 48 with an adhesive. The insulating tube 49 has a function of preventing the RF rod 62 from coming into contact with the cooling plate 30 and the second bonding layer 42. The RF rod 62 is urged upward by a spring, and the tip of the RF rod 62 is strongly pressed against the lower surface of the first bonding layer 41. The RF rod 62 is connected to an RF power supply 64 via a high pass filter (HPF) 63.

Part of the lateral surface of the first ceramic plate 21, the lateral surface of the first bonding layer 41, the lateral surface of the second ceramic plate 26, the lateral surface of the second bonding layer 42 and the lateral surface of the cooling plate 30 are covered by the insulating film 50. As the insulating film 50, a thermal spray film of e.g., alumina or yttria may be mentioned. The insulating film 50 prevents the lateral surface of the first bonding layer 41, the lateral surface of the second bonding layer 42 and the lateral surface of the cooling plate 30 from being corroded by a plasma or the like.

In the wafer placement table 10, for example, the first and second ceramic plates 21, 26 may be made of alumina, the cooling plate 30 may be made of SiSiCTi, and the first and second bonding layers 41, 42 may be made of Al. Alternatively, the first and second ceramic plates 21, 26 may be made of aluminum nitride, the cooling plate 30 may be made of Mo, and the first and second bonding layers 41, 42 may be made of Al. The first and second bonding layers 41, 42 may be formed by TCB. The cooling plate 30 may be produced so as to be divided into an upper plate and a lower plate with respect to the lower surface of the refrigerant flow path 32 as a boundary, and may be formed by bonding both plates with Al by TCB.

Next, a use example of thus configured wafer placement table 10 will be described. First, the wafer W is placed on the wafer placement surface 22 with the wafer placement table 10 installed in the chamber 90. The inside of the chamber 90 is depressurized by a vacuum pump, and adjusted to a predetermined degree of vacuum, and a direct-current voltage is applied to the electrostatic electrode 23 to generate an electrostatic attraction force to cause the wafer W to be attracted and fixed to the wafer placement surface 22 (specifically, the upper surface of the seal band 22a and the upper surfaces of the small circular projections 22b). Next, a reactive gas atmosphere having a predetermined pressure (e.g., several 10 to several 100 Pa) is created in the chamber 90, and in this state, a plasma is generated by applying a high frequency voltage across an upper electrode 92 provided in a ceiling portion in the chamber 90 and the first bonding layer 41 of the wafer placement table 10. The surface of the wafer W is treated by the generated plasma. A refrigerant is circulated through the refrigerant flow path 32 of the cooling plate 30

The wafer placement table 10 described above includes: the first bonding layer 41 made of metal, which is used as an RF electrode and configured to bond the lower surface 21b of the first ceramic plate 21 and the upper surface 26a of the second ceramic plate 26; and the second bonding layer 42 made of metal configured to bond the lower surface 26b of the second ceramic plate 26 and the upper surface 30a of the cooling plate 30. The second bonding layer 42 has higher corrosion resistance than a resin, and can reduce change with the passage of time and temperature rise in the outer peripheral portion. The thickness of the ceramic plate 20 above the second bonding layer 42 includes the thickness of the second ceramic plate 26 in addition to the thickness of the first ceramic plate 21, thus excessive cooling of the wafer W can be prevented without wastefully consuming electricity. In addition, the first ceramic plate 21 is present but the second ceramic plate 26 is not present above the first bonding layer 41 which is used as an RF electrode; thus, a favorable plasma generation efficiency is achieved.

The thickness of the first bonding layer 41 is preferably greater than or equal to 0.1 mm and less than or equal to 1 mm. When the thickness of the first bonding layer 41 is greater than or equal to 0.1 mm, the heat generated when RF propagates the first bonding layer 41 can be reduced, thus plasma can be efficiently generated. When the thickness of the first bonding layer 41 is less than or equal to 1 mm, the thermal expansion difference between the first and second ceramic plates 21, 26 and the first bonding layer 41 is unlikely to cause a problem (such as separation).

In addition, the volume resistivity of the first bonding layer 41 at 20° C. is preferably less than or equal to 1×10⁻⁴ Ωcm, and more preferably less than or equal to 1×10⁻⁵ Ωcm. In this setting, when the first bonding layer 41 is used as an RF electrode, upon application of high-frequency power across the first bonding layer 41 and the upper electrode 92, the first bonding layer 41 is unlikely to generate heat due to sufficiently low resistance of the first bonding layer 41, thus the temperature uniformity of the wafer W is unlikely to be impaired.

Furthermore, the absolute value of the difference between the linear thermal expansion coefficient of the first ceramic plate 21 at 40 to 400° C. and the linear thermal expansion coefficient of the second ceramic plate 26 at 40 to 400° C. is preferably less than or equal to 1.5×10⁻⁶/K. In this setting, occurrence of a problem (such as cracking) due to the thermal expansion difference between the first ceramic plate 21 and the second ceramic plate 26 can be reduced.

The cooling plate 30 is made of metal or a metal ceramic composite material, and the absolute value of the difference between the linear thermal expansion coefficients of the cooling plate 30 and the second ceramic plate 26 at 40 to 400° C. is preferably less than or equal to 1.5×10⁻⁶/K. In this setting, occurrence of a problem (such as cracking) due to the thermal expansion difference between the second ceramic plate 26 and the cooling plate 30 can be reduced.

In addition, the RF electrode hole 48 has the insulating tube 49 through which the RF rod 62 is inserted. Thus, even when the cooling plate 30 has an electrical conductivity, and the RF rod 62 is a metal rod, it is possible to prevent short-circuit due to contact between the RF rod 62 and the cooling plate 30 or the second bonding layer 42.

In the wafer placement table 10, a bonded structure is used as the ceramic plate 20, the bonded structure being obtained by bonding the first ceramic plate 21 with the built-in electrostatic electrode 23, and the second ceramic plate 26 together via the first bonding layer 41 serving as an RF electrode; however, one ceramic plate with built-in electrostatic electrode and RF electrode may be used. However, when an RF electrode is built in the ceramic plate, the RF electrode needs to be thin (about several 10 μm) to prevent separation of the RF electrode material and the ceramic material due to the thermal expansion difference therebetween at the time of manufacturing. In recent years, there has been demand to use high-power plasma; however, with a thin RF electrode, heat is generated significantly at its connection portion to the RF rod, thus the temperature uniformity of the wafer W may be impaired. In contrast, in the wafer placement table 10, the first bonding layer 41 is utilized as an RF electrode; thus, the first bonding layer 41 can be thickened (greater than or equal to 0.1 mm), and heat generation at its connection portion to the RF rod 62 can be reduced.

Note that the present invention is not limited to the above-described embodiment at all, and it is needless to say that the present invention can be carried out in various forms as long as the forms belong to the technical scope of the present invention.

In the above-described embodiment, a bonding layer made of metal is used as the second bonding layer 42; however, a bonding layer made of inorganic composition may be used. As the inorganic composition, glass such as quartz glass and soda glass, and an inorganic adhesive containing ceramic may be mentioned.

In the above-described embodiment, the wafer placement table 10 may have a plurality of holes which penetrate the wafer placement table 10 in a vertical direction. These holes include a plurality of gas holes opened in the wafer placement surface 22, and lift pin holes for inserting lift pins to vertically move the wafer W with respect to the wafer placement surface 22. The plurality of gas holes are provided at appropriate positions where the seal band 22a and the small circular projections 22b are not provided in a plan view of the wafer placement surface 22. A heat transfer gas such as He gas is supplied to the gas holes. When a heat transfer gas is supplied to the gas holes, the heat transfer gas is filled in the space near the lower surface of the wafer W placed on the wafer placement surface 22. Consequently, favorable heat transfer between the wafer W and the wafer placement table 10 is achieved. A plurality of lift pin holes are provided at regular intervals along a concentric circle of the wafer placement surface 22 in a plan view of the wafer placement surface 22. The vertical move of the lift pins can raise the wafer W from the wafer placement surface 22 or lower the wafer W to the wafer placement surface 22.

In the above-described embodiment, the first bonding layer 41 is connected to the RF power supply 64, and the upper electrode 92 is connected to the ground; however, the first bonding layer 41 may be connected to the ground, and the upper electrode 92 may be connected to the RF power supply 64.

In the above-described embodiment, the electrostatic electrode 23 is built in the first ceramic plate 21; however, in replacement of or in addition to the electrostatic electrode 23, a heater electrode may be built in the first ceramic plate 21. To build in the heater electrode, a resistance heating element (such as a coil, a ribbon) may be wired over the entire surface of the wafer placement surface 22 in a plan view, or the wafer placement surface 22 may be divided into a plurality of zones in a plan view, and a resistance heating element may be wired for each zone. When a heater electrode is built in the first ceramic plate 21 along with the electrostatic electrode 23, the electrostatic electrode 23 is built in near the wafer placement surface 22, and the heater electrode is built in under the electrostatic electrode 23.

International Application No. PCT/JP2023/045983, filed on Dec. 21, 2023, is incorporated herein by reference in its entirety.

What is claimed is:

1. A member for semiconductor manufacturing apparatus, comprising:
a first ceramic plate having a wafer placement surface on its upper surface and a built-in electrode;
a second ceramic plate disposed on a lower surface side of the first ceramic plate;
a cooling plate disposed on a lower surface side of the second ceramic plate;
a first bonding layer made of metal, which is used as an RF electrode and configured to bond the lower surface of the first ceramic plate and an upper surface of the second ceramic plate together; and
a second bonding layer made of metal or inorganic composition configured to bond the lower surface of the second ceramic plate and an upper surface of the cooling plate together.

2. The member for semiconductor manufacturing apparatus according to claim 1,
wherein a thickness of the first bonding layer is greater than or equal to 0.1 mm and less than or equal to 1 mm.

3. The member for semiconductor manufacturing apparatus according to claim 1,
wherein a volume resistivity of the first bonding layer at 20° C. is lower than or equal to 1×10⁻⁴ Ωcm.

4. The member for semiconductor manufacturing apparatus according to claim 1,
wherein an absolute value of a difference between a linear thermal expansion coefficient of the first ceramic plate at 40 to 400° C. and a linear thermal expansion coefficient of the second ceramic plate at 40 to 400° C. is less than or equal to 1.5×10⁻⁶/K.

5. The member for semiconductor manufacturing apparatus according to claim 4,
wherein the cooling plate is made of metal or a metal ceramic composite material, and an absolute value of a difference between linear thermal expansion coefficients of the cooling plate at 40 to 400° C. and the second ceramic plate at 40 to 400° C. is less than or equal to 1.5×10⁻⁶/K.

6. The member for semiconductor manufacturing apparatus according to claim 1, further comprising
an RF electrode hole, through which an RF electrode connection member to be directly connected to the first bonding layer is inserted, is provided from a lower surface of the cooling plate to the first bonding layer penetrating through the cooling plate, the second bonding layer and the second ceramic plate.

7. The member for semiconductor manufacturing apparatus according to claim 6,
wherein the RF electrode hole has an insulating tube through which the RF electrode connection member is inserted.
